(19) United States
(12) Patent Application Publication
(10) Pub. No.: US 2015/0263039 A1
(43) Pub. Date: Sep. 17, 2015

(54) STANDARD CELL LAYOUT FOR LOGIC GATE

(71) Applicants: Paramjeet Singh, Delhi (IN); Shahab Akhtar, New Delhi (IN); Manmohan Rana, Ghaziabad (IN)

(72) Inventors: Paramjeet Singh, Delhi (IN); Shahab Akhtar, New Delhi (IN); Manmohan Rana, Ghaziabad (IN)

(21) Appl. No.: 14/207,482

(22) Filed: Mar. 12, 2014

(51) Int. Cl. H01L 27/118

(52) U.S. Cl. CPC H01L 27/11807; H01L 2027/11812; H01L 2027/11866; H01L 2027/11881; H01L 2027/11816; H01L 2027/11831

(57) ABSTRACT

A standard cell layout for a multiple input logic gate includes first through fourth parallel gate electrodes disposed over first and second active regions. The first and second gate electrodes are disposed on a first side of a first axis at first and second distances, respectively, from the first axis, and the third and fourth gate electrodes are disposed on a second side of the first axis at third and fourth distances, respectively, from the first axis. The first distance is greater than the second distance and the fourth distance is greater than the third distance. The third and fourth gate electrodes form a mirror image of the first and second gate electrodes about the first axis.

### BACKGROUND OF THE INVENTION

The present invention relates generally to integrated circuits (ICs), and more particularly, to a standard cell layout for a logic gate of an IC.

Integrated circuits include sets of miniature circuit components placed on a semiconductor material. In the nascent stage of the IC industry, only a few circuit components could be placed on a single wafer of the semiconductor material, whereas today, an integrated circuit can include millions of transistors. With the increase in the number of circuit components on an IC, new design techniques and methodologies have been developed. Design tools, such as electronic design automation (EDA) and computer-aided design (CAD) tools, are widely used to design ICs. Examples of advanced ICs include microprocessors, memories, systems on a chip (SOC), and application-specific integrated circuits (ASICs). Standard cell methodology is a technique of designing ICs with a focus on the logic functions used in the IC. A standard cell includes multiple transistors that are interconnected to implement desired logic functions, such as AND, OR, NOT, XOR, and XNOR, as well as storage functions (e.g., flip-flops, latches, and buffers).

A standard cell library includes various standard cells having predetermined heights and widths. The standard cell library may include multiple standard cells for a single logic function that differ in area, speed, and power consumption. Designers can select the desired standard cells from the standard cell library based on the area, speed, and power consumption requirements of the IC and arrange the standard cells in rows and columns. Once a schematic view (a view that illustrates the terminals of the multiple transistors and the interconnections thereof) of the IC is generated by the design tool, the IC design is simulated, a layout view (a view that illustrates the actual physical implementation of the standard cells) of the IC design is generated and verified before fabrication of the IC. The cost of production of the IC is directly proportional to its layout area. Thus, there is a desire to design smaller ICs without compromising performance.

FIG. 1 is a schematic layout diagram of a conventional standard cell 100 of a 2-input NOR logic gate. The standard cell 100 includes first and second active regions 102a and 102b, first through twelfth metal layers 104a-104l (collectively referred to as metal layers 104), first through fourth gate electrodes 106a-106d (collectively referred to as gate electrodes 106), and first through nineteenth metal contacts 108a-108s (collectively referred to as metal contacts 108). The metal layers 104 are implemented as power layers and signal layers. The signal layers route clock signals and input signals. The metal layers 104a and 104b form power supply (V_{dd}) and ground (vₛₛ) terminals, respectively. The gate electrodes 106 are disposed over the first and second active regions 102a and 102b. The first and second gate electrodes 106a and 106b form a first folded transistor FT1 in the first active region 102a and a third folded transistor FT3 in the second active region 102b. The third and fourth gate electrodes 106c and 106d form a second folded transistor FT2 in the first active region 102a and a fourth folded transistor FT4 in the second active region 102b. The first and second active regions 102a and 102b include a plurality of source and drain regions that are formed adjacent to the gate electrodes 106. The first and second folded transistors FT1 and FT2 are p-type metal-oxide semiconductor (PMOS) transistors and the third and fourth folded transistors FT3 and FT4 are n-type MOS (NMOS) transistors.

The first gate electrode 106a is connected to the second gate electrode 106b by way of the metal layer 104g and the metal contacts 108i and 108j. The third gate electrode 106c is connected to the fourth gate electrode 106d by way of the metal layer 104h and the metal contacts 108k and 108l. The metal layers 104g and 104h receive first and second inputs, respectively. The metal layer 104a connects power supply (V_{dd}) to the source region of the first folded transistor FT1 by way of the metal layer 104i and the metal contacts 108m and 108o. A portion of the first active region 102a formed between the gate electrodes 106a and 106b forms the source region of the first folded transistor FT1. The first and second folded transistors FT1 and FT2 share a portion of the first active region 102a that is formed between the gate electrodes 106b and 106c. This shared portion of the first active region 102a forms the drain and source regions of the first and the second folded transistors, FT1 and FT2, respectively. The drain regions of the first folded transistor FT1 are connected to the source regions of the second folded transistor FT2 by way of the metal layer 104j and the metal contacts 108q, 108r, and 108s. The drain region of the second folded transistor FT2 is connected to the drain regions of the third and fourth folded transistors FT3 and FT4 by way of the metal layers 104f and 104l and the metal contacts 108p, 108h, and 108g. The metal layer 104b connects ground to the source regions of the third and fourth folded transistors FT3 and FT4 by way of the metal layers 104c, 104d, and 104e and the metal contacts 108a, 108b, 108c, 108d, 108e, and 108f. An output signal Vₒᵤₜ is obtained at the metal layer 104k from the metal layer 104l by way of the metal contact 108n. The metal layers 104 may be metal-1 layers or metal-2 layers. The metal-1 layers are connected to the drain and source regions by way of metal contacts while the metal-2 layers are connected thereto by way of a combination of the metal contacts and vias.

FIG. 2 is a schematic layout diagram of a conventional standard cell 200 of a 2-input NAND logic gate. The standard cell 200 includes first and second active regions 202a and 202b, first through twelfth metal layers 204a-204l (collectively referred to as metal layers 204), first through fourth gate electrodes 206a-206d (collectively referred to as gate electrodes 206), and first through nineteenth metal contacts 208a-208s (collectively referred to as metal contacts 208). The metal layers 204 are implemented as power layers and signal layers. The signal layers route clock signals and input signals. The metal layers 204a and 204b form power supply (V_{dd}) and ground (vₛₛ) terminals, respectively. The gate electrodes 206 are disposed over the first and second active regions 202a and 202b. The first and second gate electrodes 206a and 206b form a first folded transistor FT1 in the first active region 202a and a third folded transistor FT3 in the second active region 202b. The third and fourth gate electrodes 206c and 206d form a second folded transistor FT2 in the first active region 202a and a fourth folded transistor FT4 in the second active region 202b. The first and second active regions 202a and 202b include a plurality of source and drain regions that are formed adjacent to the gate electrodes 206. The first and second folded transistors FT1 and FT2 are PMOS transistors and the third and fourth folded transistors FT3 and FT4 are NMOS transistors.

The first gate electrode 206a is connected to the second gate electrode 206b by way of the metal layer 204e and the metal contacts 208g and 208h. The third gate electrode 206c is connected to the fourth gate electrode 206d by way of the metal layer 204f and the metal contacts 208i and 208j. The metal layers 204e and 204f receive first and second input signals, respectively. The metal layer 204a connects power supply (V_{dd}) to the source regions of the first and second folded transistors FT1 and FT2 by way of the metal layers 204i, 204j, and 204k and the metal contacts 208o, 208n, 208p, 208q, 208r, and 208s. The drain regions of the first and second folded transistors FT1 and FT2 are connected by way of the metal layer 204l and the metal contacts 208l and 208m. The drain region of the second folded transistor FT2 that is formed between the third and fourth gate electrodes 206c and 206d is connected to the drain region of the fourth folded transistor FT4 that is formed between the gate electrodes 206c and 206d, by way of the metal layer 204g and the metal contacts 208m and 208f. The third and fourth folded transistors FT3 and FT4 share a portion of the second active region 202b that is formed between the gate electrodes 206b and 206c. This shared portion of the second active region 202b forms the drain and source regions of the third and fourth folded transistors FT3 and FT4, respectively. The drain regions of the third folded transistor FT3 are connected to the source regions of the fourth folded transistor FT4 by way of the metal layer 204c and the metal contacts 208a, 208b, and 208c. The metal layer 204b connects ground to the source region of the third folded transistor FT3 that is formed between the gate electrodes 206a and 206b by way of the metal layer 204d, and the metal contacts 208e and 208d. An output signal Vₒᵤₜ is obtained at the metal layer 204h from the metal layer 204g by way of the metal contact 208k.

The metal layers 104a of the standard cells 100 and 204b of the standard cell 200 that form the power and ground terminals, respectively, have narrow widths and are not placed at the top of the standard cells 100 and 200. There are specific design rules to design the standard cells, and it is essential for the metal layers that form the power and ground terminals to have wider widths, as metal layers with wide widths have lower resistance and thus exhibit better signal conductivity.

FIG. 3 is a schematic layout diagram of a conventional standard cell 300 of a 3-input NOR gate. The standard cell 300 includes first and second active regions 302a and 302b, first through thirteenth metal layers 304a-304m (collectively referred to as metal layers 304), first through eighth gate electrodes 306a-306h (collectively referred to as gate electrodes 306), and first through twenty-fifth metal contacts 308a-308y (collectively referred to as metal contacts 308). The metal layers 304 are implemented as power layers and signal layers. The signal layers route clock signals and input signals. The metal layers 304a and 304b form power supply (V_{dd}) and ground (vₛₛ) terminals, respectively. The gate electrodes 306 are disposed over the first and second active regions 302a and 302b. The first and second gate electrodes 306a and 306b form a first folded transistor FT1 in the first active region 302a and a fourth folded transistor FT4 in the second active region 302b. The third and sixth gate electrodes 306c and 306f form a second folded transistor FT2 in the first active region 302a and a fifth folded transistor FT5 in the second active region 302b. The fourth and fifth gate electrodes 306d and 306e form a third folded transistor FT3 in the first active region 302a and a sixth folded transistor FT6 in the second active region 302b. The first and second active regions 302a and 302b include a plurality of source and drain regions that are formed adjacent to the gate electrodes 306. The first, second, and third folded transistors FT1, FT2, and FT3 are PMOS transistors and the fourth, fifth, and sixth folded transistors FT4, FT5, and FT6 are NMOS transistors.

The seventh gate electrode 306g connects the first and second gate electrodes 306a and 306b. The eighth gate electrode 306h connects the fourth and fifth gate electrodes 306d and 306e. The metal layers 304h, 304i, and 304j receive first, second, and third input signals, respectively. The metal layer 304a connects power supply (V_{dd}) to the source region of the third folded transistor FT3 by way of the metal layer 304m and the metal contacts 308x and 308w. A portion of the first active region 302a that is formed between the gate electrodes 306d and 306e forms the source region of the third folded transistor FT3. The first and second folded transistors FT1 and FT2 share a portion of the first active region 302a that is formed between the gate electrodes 306b and 306c. This shared portion of the first active region 302a forms the source and drain regions of the first and second folded transistors, FT1 and FT2, respectively. The second and third folded transistors FT2 and FT3 share a portion of the first active region 302a that is formed between the gate electrodes 306e and 306f. This shared portion of the first active region 302a forms the source and drain regions of the second and third folded transistors FT2 and FT3, respectively. The drain regions of the third folded transistor FT3 are connected by way of the metal layer 304k and the metal contacts 308s and 308t. The source regions of the first folded transistor FT1 are connected to the drain regions of the second folded transistor FT2 by way of the metal layer 304l and the metal contacts 308u, 308y, and 308v. The drain region of the first folded transistor FT1 is connected to the drain regions of the fourth, fifth, and sixth folded transistors FT4, FT5, and FT6 by way of the metal layer 304g and the metal contacts 308r, 308k, 308l, and 308m. The metal layer 304b connects ground to the source regions of the fourth, fifth, and sixth folded transistors FT4, FT5, and FT6 by way of the metal layers 304c, 304d, 304e, and 304f and first through tenth metal contacts 308a-308j. An output signal Vₒᵤₜ is obtained at the metal layer 304g.

FIG. 4 is a schematic layout diagram of a conventional standard cell 400 of a 3-input NAND gate. The standard cell 400 includes first through fourth active regions 402a-402d, first through fifteenth metal layers 404a-404o (collectively referred to as metal layers 404), first through ninth gate electrodes 406a-406i (collectively referred to as gate electrodes 406), and first through thirtieth metal contacts 408a-409d (collectively referred to as metal contacts 408). The first and third active regions 402a and 402c have the same conductivities and the second and third active regions 402b and 402d have the same conductivities. The metal layers 404 are implemented as power layers and signal layers. The signal layers route clock signals and input signals. The metal layers 404a and 404b form power supply (V_{dd}) and ground (vₛₛ) terminals, respectively. The gate electrodes 406 are disposed over the first through fourth active regions 402a-402d. The first and second gate electrodes 406a and 406b form a first folded transistor FT1 in the first active region 402a and a fourth folded transistor FT4 in the second active region 402b. The third and fourth gate electrodes 406c and 406d form a second folded transistor FT2 in the first active region 402a and a fifth folded transistor FT5 in the second active region 402b. The fifth and sixth gate electrodes 406e and 406f form a third folded transistor FT3 in the third active region 402c and a sixth folded transistor FT6 in the fourth active region 402d. The first through fourth active regions 402a-402d include a plurality of source and drain regions that are formed adjacent to the gate electrodes 406. The first, second, and third folded transistors FT1, FT2, and FT3 are PMOS transistors and the fourth, fifth, and sixth folded transistors FT4, FT5, and FT6 are NMOS transistors.

The seventh gate electrode 406g connects the first and second gate electrodes 406a and 406b. The eighth gate electrode 406h connects the third and fourth gate electrodes 406c and 406d. The ninth gate electrode 406i connects the fifth and sixth gate electrodes 406e and 406f. The metal layers 404f, 404h, and 404j receive first, second, and third input signals, respectively. The metal layer 404a connects power supply (V_{dd}) to the source regions of the first, second, and third folded transistors FT1, FT2, and FT3 by way of the metal layers 404k, 404l, 404m, 404n, and 404o and the metal contacts 408r, 408s, 408t, 408w, 408x, 408y, 408z, 409c, and 409d. The drain regions of the first, second, and third folded transistors FT1, FT2, and FT3 are connected by way of the metal layer 404g and the metal contacts 408q, 408p, 408u, 408v, 409a, and 409b. The drain region of the first folded transistor FT1 is connected to the drain region of the fourth folded transistor FT4 by way of the metal layer 404g and the metal contacts 408q, 408p, and 408h. The fourth and fifth folded transistors FT4 and FT5 share a portion of the second active region 402b that is formed between the gate electrodes 406b and 406c. This shared portion of the second active region 402b forms the source and drain regions of the fourth and fifth folded transistors FT4 and FT5, respectively. The source regions of the fourth folded transistor FT4 are connected to the drain regions of the fifth folded transistor FT5 by way of the metal layer 404c and the metal contacts 408a, 408b, and 408c. The source region of the fifth folded transistor FT5 that is formed between the third and fourth gate electrodes 406c and 406d is connected to the drain region of the sixth folded transistor FT6 that is formed between the fifth and sixth gate electrodes 406e and 406f by way of the metal layer 404i and the metal contacts 408i, 408j, and 408f. The metal layer 404b connects ground to the source regions of the sixth folded transistor FT6 by way of the metal layers 404d and 404e and the metal contacts 408d, 408g, and 408e. An output signal Vₒᵤₜ is obtained at the metal layer 404g.

As the standard cell 400 is designed by conforming to the design rules, the formation of the third and sixth folded transistors FT3 and FT6 in the third and fourth active regions 402c and 402d leads to an increase in the area of the standard cell 400. Diffusion capacitance of a standard cell is less when folded transistors in the standard cell share the active regions as compared to a standard cell with folded transistors on separate active regions. The placement of the third and sixth folded transistors FT3 and FT6 in the third and fourth active regions 402c and 402d, thus, results in an increased diffusion capacitance of the standard cell 400.

The areas of the standard cells of FIGS. 1, 2, 3, and 4 depend on the metal layers therein. A minimum width of a metal layer along with a minimum spacing between the metal layer and an adjacent metal layer is known as a routing pitch. In an example, when a width of the metal layer is 4 lambdas and requires a spacing of 4 lambdas between the metal layer and the adjacent metal layer in the standard cell, the track pitch of the standard cell is 8 lambdas. The height of the standard cell is determined by multiplying the track pitch with the number of routing tracks along the height of the standard cell. It will be apparent to those skilled in the art that the metal layers may be metal-1 layers or metal-2 layers. An increase in the number of metal-1 layers results in an increase in the area of the standard cell while an addition of metal-2 layer will result in an increase in the cost of production of the standard cell. The resistance of the metal layer is a function of the dimensions thereof and a property of the material of the metal layer. The capacitance of the metal layer is a function of the placement of the metal layers in the standard cell. The adjacent metal layers exhibit parallel plate capacitance. The parallel plate capacitance is a function of the dimensions of the metal layers, the spacing between the adjacent metal layers, and the relative permittivity of a dielectric material therebetween. The metal layers thus introduce a delay in the routing of signals due to their resistances and capacitances. Consequently, the timing of signals in the standard cell, and hence the performance of the IC, are hampered.

Therefore, it would be advantageous to have a layout of a standard cell with reduced area, reduced routing delay, and reduced shallow trench isolation (STI) stress effect, and uses fewer metal layers.

### BRIEF DESCRIPTION OF THE DRAWINGS

The following detailed description of the preferred embodiments of the present invention will be better understood when read in conjunction with the appended drawings. The present invention is illustrated by way of example, and not limited by the accompanying figures, in which like references indicate similar elements.

FIG. 1 is a schematic layout diagram of a conventional standard cell of a 2-input NOR logic gate;

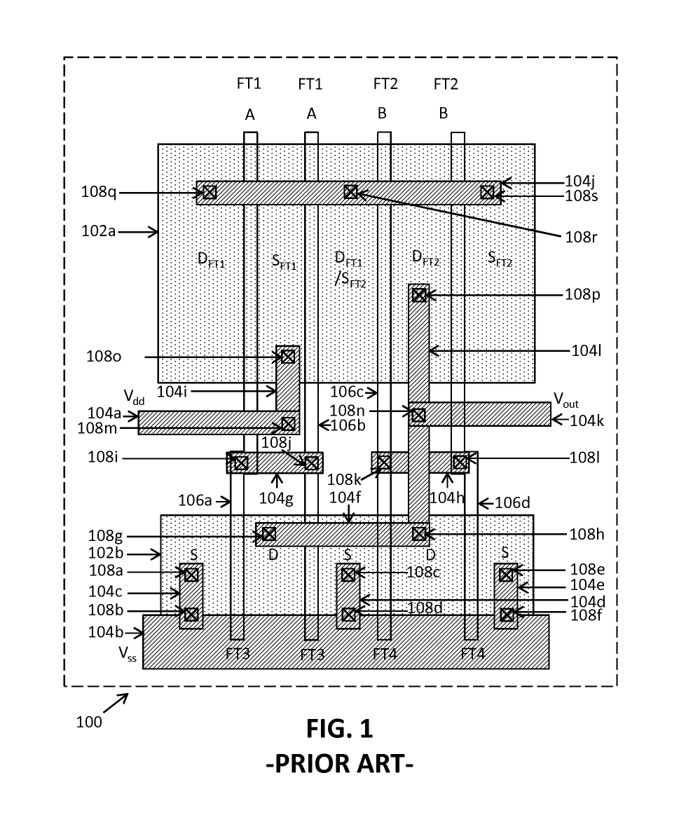

FIG. 2 is a schematic layout diagram of a conventional standard cell of a 2-input NAND logic gate;

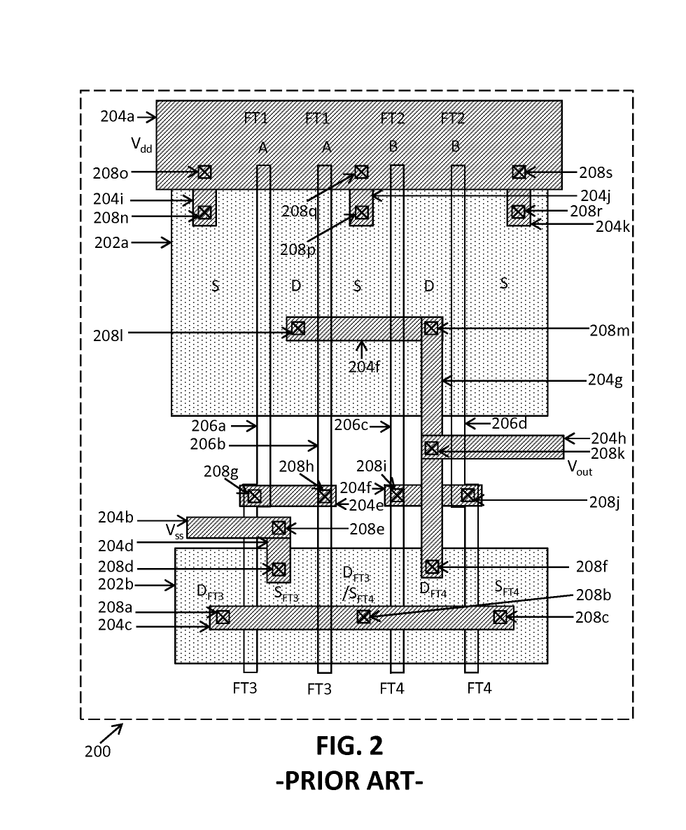

FIG. 3 is a schematic layout diagram of a conventional standard cell of a 3-input NOR logic gate;

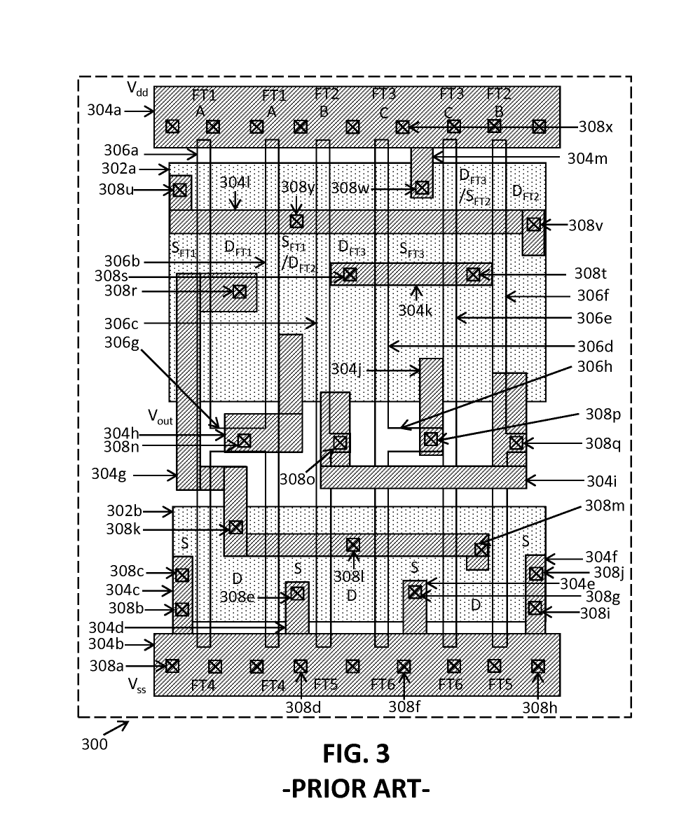

FIG. 4 is a schematic layout diagram of a conventional standard cell of a 3-input NAND logic gate;

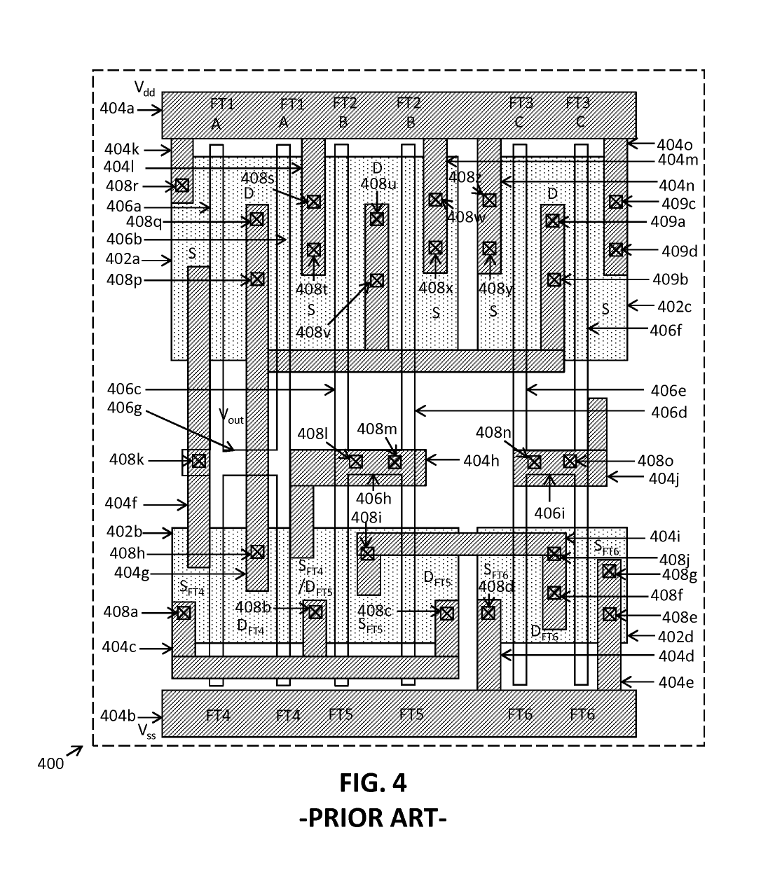

FIG. 5 is a schematic layout diagram of a standard cell of a 2-input NOR logic gate in accordance with an embodiment of the present invention;

FIG. 6 is a schematic layout diagram of a standard cell of a 2-input NAND logic gate in accordance with an embodiment of the present invention;

FIG. 7 is a schematic layout diagram of a standard cell of a 3-input NOR logic gate in accordance with an embodiment of the present invention;

FIG. 8 is a schematic layout diagram of a standard cell of a 3-input NAND logic gate in accordance with an embodiment of the present invention;

FIG. 9 is a schematic layout diagram of a standard cell of a 2-input NOR logic gate in accordance with another embodiment of the present invention; and

FIG. 10 is a schematic layout diagram of a standard cell of a 2-input NAND logic gate in accordance with another embodiment of the present invention.

### DETAILED DESCRIPTION OF PREFERRED EMBODIMENTS

The detailed description of the appended drawings is intended as a description of the currently preferred embodiments of the present invention, and is not intended to represent the only form in which the present invention may be practiced. It is to be understood that the same or equivalent functions may be accomplished by different embodiments that are intended to be encompassed within the spirit and scope of the present invention.

In an embodiment of the present invention, a standard cell layout is provided. The standard cell includes a plurality of active regions including first and second active regions that are formed in a semiconductor substrate. The first and second active regions are formed on first and second sides of a first axis. The second active region is spaced apart from the first active region. A plurality of gate fingers are formed over the first and second active regions such that first and second gate fingers of the plurality of gate fingers are formed on the first side of the first axis, and third and fourth gate fingers of the plurality of gate fingers are formed on the second side of the first axis. The first, second, third, and fourth gate fingers are substantially parallel to the first axis and are disposed at first, second, third, and fourth distances, respectively, from the first axis. The first distance is greater than the second distance and the fourth distance is greater than the third distance. A plurality of gate connectors including first and second gate connectors electrically connect the second and third gate fingers, and the first and fourth gate fingers, respectively, such that the first active region forms a first folded transistor with the first and fourth gate fingers and a second folded transistor with the second and third gate fingers, and the second active region forms a third folded transistor with the first and fourth gate fingers and a fourth folded transistor with the second and third gate fingers.

In another embodiment of the present invention, a standard cell layout is provided. The standard cell includes a plurality of active regions including first and second active regions that are formed in a semiconductor substrate. The first and second active regions are formed on first and second sides of a first axis. The second active region is spaced apart from the first active region. A plurality of gate fingers are formed over the first and second active regions such that first, second, and third gate fingers of the plurality of gate fingers are formed on the first side of the first axis, and fourth, fifth, and sixth gate fingers of the plurality of gate fingers are formed on the second side of the first axis. The first, second, third, fourth, fifth, and sixth gate fingers are substantially parallel to the first axis and are disposed at first, second, third, fourth, fifth, and sixth distances respectively, from the first axis. The first and second distances are greater than the third distance and the fifth and sixth distances are greater than the fourth distance. A plurality of gate connectors including first, second, and third gate connectors electrically connect the third and fourth gate fingers, the second and fifth gate fingers, and the first and sixth gate fingers, respectively, such that the first active region forms a first folded transistor with the first and sixth gate fingers, a second folded transistor with the second and fifth gate fingers, and a third folded transistor with the third and fourth gate fingers, and the second active region forms a fourth folded transistor with the first and sixth gate fingers a fifth folded transistor with the second and fifth gate fingers, and a sixth folded transistor with the third and fourth gate fingers.

Various embodiments of the present invention provide a standard cell layout. The standard cell includes first and second active regions that are formed in a semiconductor substrate. The first and second active regions are formed on first and second sides of a first axis. The second active region is spaced apart from the first active region. A plurality of gate fingers are formed over the first and second active regions such that first and second gate fingers of the plurality of gate fingers are formed on the first side of the first axis, and third and fourth gate fingers of the plurality of gate fingers are formed on the second side of the first axis. The first, second, third, and fourth gate fingers are substantially parallel to the first axis and are disposed at first, second, third, and fourth distances, respectively, from the first axis. The first distance is greater than the second distance and the fourth distance is greater than the third distance. A plurality of gate connectors including first and second gate connectors electrically connect the second and third gate fingers, and the first and fourth gate fingers, respectively, such that the first active region forms a first folded transistor with the first and fourth gate fingers and a second folded transistor with the second and third gate fingers, and the second active region forms a third folded transistor with the first and fourth gate fingers and a fourth folded transistor with the second and third gate fingers. First and second input signals are received at the second and first gate connectors, respectively. The third and fourth gate fingers form a mirror image of the first and second gate fingers about the first axis. Such an arrangement of the gate fingers leads to use of fewer gate connectors to implement logic functions in the standard cell layout. As a result of fewer gate connectors in the standard cell layout, the height thereof decreases resulting in a reduction of the standard cell layout area. Delay introduced in routing of signals by the gate connectors is also reduced resulting in an improved performance of the standard cell.

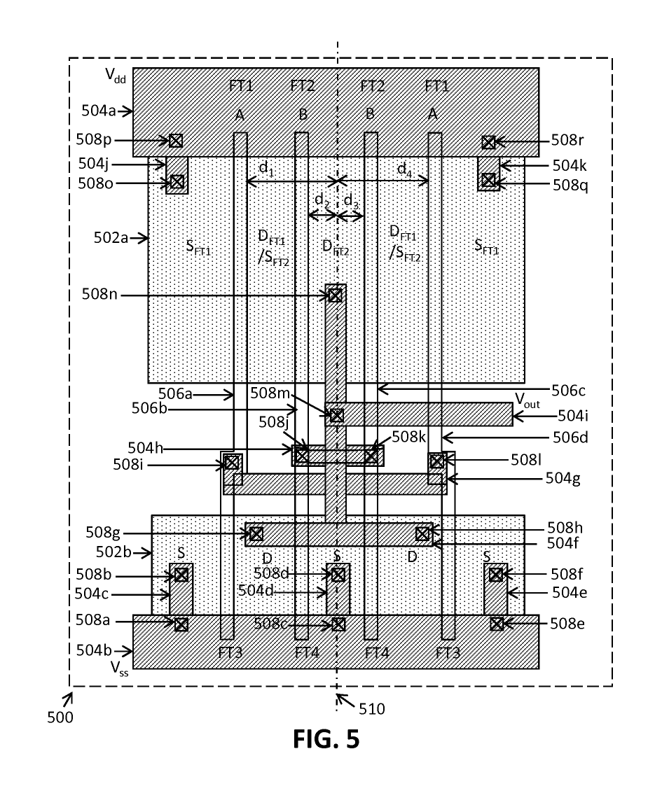

Referring now to FIG. 5, a schematic layout diagram of a standard cell 500 of a 2-input NOR gate in accordance with an embodiment of the present invention is shown. The standard cell 500 includes first and second active regions 502a and 502b, first through eleventh metal layers 504a-504k (collectively referred to as metal layers 504), first through fourth gate electrodes 506a-506d (collectively referred to as gate electrodes 506), and first through eighteenth metal contacts 508a-508r (collectively referred to as metal contacts 508). The metal layers 504 are implemented as power layers and signal layers. The signal layers route clock signals and input signals. The metal layers 504a and 504b form power supply (V_{dd}) and ground (vₛₛ) terminals, respectively. The gate electrodes 506 are disposed over the first and second active regions 502a and 502b. The first and fourth gate electrodes 506a and 506d form a first folded transistor FT1 in the first active region 502a and a third folded transistor FT3 in the second active region 502b. The second and third gate electrodes 506b and 506c form a second folded transistor FT2 in the first active region 502a and a fourth folded transistor FT4 in the second active region 502b. The first and second active regions 502a and 502b include a plurality of source and drain regions that are formed adjacent to the gate electrodes 506. The first and second folded transistors FT1 and FT2 are PMOS transistors and the third and fourth folded transistors FT3 and FT4 are NMOS transistors.

The first and second gate electrodes 506a and 506b are disposed on a first side of an axis 510 at first and second distances d1 and d2, respectively, from the axis 510. The third and fourth gate electrodes 506c and 506d are formed on a second side of the axis 510 at third and fourth distances d3 and d4, respectively, from the axis 510. The first distance d1 is greater than the second distance d2 and the fourth distance d4 is greater than the third distance d3. The gate electrodes 506 are disposed such that they are symmetric about the axis 510. The first gate electrode 506a is connected to the fourth gate electrode 506d by way of the metal layer 504g and the metal contacts 508i and 508l. The second gate electrode 506b is connected to the third gate electrode 506c by way of the metal layer 504h and the metal contacts 508j and 508k. The metal layers 504g and 504h receive first and second input signals, respectively. The metal layer 504a connects power supply (V_{dd}) to the source regions of the first folded transistor FT1 by way of the metal layers 504j and 504k and the metal contacts 508o, 508p, 508q, and 508r. The first and second folded transistors FT1 and FT2 share first and second portions of the first active region 502a that are formed on the first and second sides of the axis 510, respectively. The shared first portion on the first side of the axis 510 is formed between the gate electrodes 506a and 506b. The shared second portion on the second side of the axis 510 is formed between the gate electrodes 506c and 506d. The shared first and second portions of the first active region 502a form the drain and source regions of the first and second folded transistors FT1 and FT2, respectively. The drain region of the second folded transistor FT2 that is formed between the second and third gate electrodes 506b and 506c is connected to the drain regions of the third and fourth folded transistors FT3 and FT4 by way of the metal layer 504f and the metal contacts 508n, 508g, and 508h. The metal layer 504b connects ground to the source regions of the third and fourth folded transistors FT3 and FT4 by way of the metal layers 504c, 504d, and 504e and the metal contacts 508a, 508b, 508c, 508d, 508e, and 508f. An output signal Vₒᵤₜ is obtained at the metal layer 504i by way of the metal contact 508m from the metal layer 504f. The metal layers 504 may be metal-1 layers or metal-2 layers. The metal-1 layers are connected to the drain and source regions by way of metal contacts while the metal-2 layers are connected thereto by way of a combination of the metal contacts and vias.

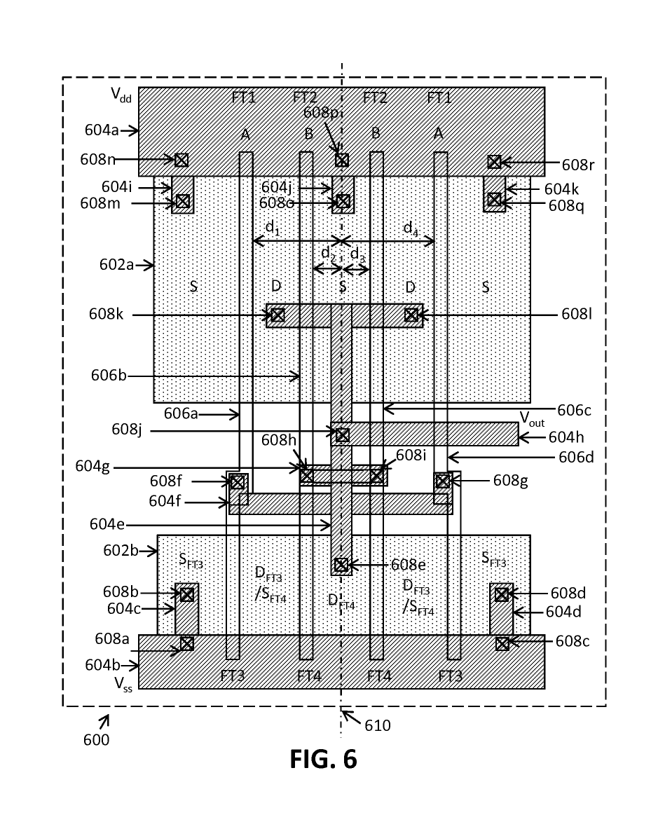

Referring now to FIG. 6, a schematic layout diagram of a standard cell 600 of a 2-input NAND gate in accordance with an embodiment of the present invention is shown. The standard cell 600 includes first and second active regions 602a and 602b, first through eleventh metal layers 604a-604k (collectively referred to as metal layers 604), first through fourth gate electrodes 606a-606d (collectively referred to as gate electrodes 606), and first through eighteenth metal contacts 608a-608r (collectively referred to as metal contacts 608). The metal layers 604 are implemented as power layers and signal layers. The signal layers route clock signals and input signals. The metal layers 604a and 604b form power supply (V_{dd}) and ground (vₛₛ) terminals, respectively. The gate electrodes 606 are disposed over the first and second active regions 602a and 602b. The first and fourth gate electrodes 606a and 606d form a first folded transistor FT1 in the first active region 602a and a third folded transistor FT3 in the second active region 602b. The second and third gate electrodes 606b and 606c form a second folded transistor FT2 in the first active region 602a and a fourth folded transistor FT4 in the second active region 602b. The first and second active regions 602a and 602b include a plurality of source and drain regions that are formed adjacent to the gate electrodes 606. The first and second folded transistors FT1 and FT2 are PMOS transistors and the third and fourth folded transistors FT3 and FT4 are NMOS transistors.

The first and second gate electrodes 606a and 606b are disposed on a first side of an axis 610 at first and second distances d1 and d2, respectively, from the axis 610. The third and fourth gate electrodes 606c and 606d are formed on a second side of the axis 610 at third and fourth distances d3 and d4, respectively, from the axis 610. The first distance d1 is greater than the second distance d2 and the fourth distance d4 is greater than the third distance d3. The gate electrodes 606 are disposed such that they are symmetric about the axis 610. The first gate electrode 606a is connected to the fourth gate electrode 606d by way of the metal layer 604f and the metal contacts 608f and 608g. The second gate electrode 606b is connected to the third gate electrode 606c by way of the metal layer 604g and the metal contacts 608h and 608i. The metal layers 604f and 604g receive first and second input signals, respectively. The metal layer 604a connects power supply (V_{dd}) to the source regions of the first and second folded transistors FT1 and FT2 by way of the metal layers 604i, 604j, and 604k and the metal contacts 608m, 608n, 608o, 608p, 608q, and 608r. The drain regions of the first and second folded transistors FT1 and FT2 are connected to the drain region of the fourth folded transistor FT4 that is formed between the second and third gate electrodes 606b and 606c by way of the metal layer 604e and the metal contacts 608k, 608l, and 608e. The third and fourth folded transistors FT3 and FT4 share first and second portions of the second active region 602b that are formed on the first and second sides of the axis 610, respectively. The shared first portion on the first side of the axis 610 is formed between the gate electrodes 606a and 606b. The shared second portion on the second side of the axis 610 is formed between the gate electrodes 606c and 606d. The shared first and second portions of the second active region 602b form the drain and source regions of the third and fourth folded transistors FT3 and FT4, respectively. The metal layer 604b connects ground to the source regions of the third folded transistor FT3 by way of the metal layers 604c and 604d and the metal contacts 608a, 608b, 608c, and 608d. An output signal Vₒᵤₜ is obtained at the metal layer 604h by way of the metal contact 608j from the metal layer 604e.

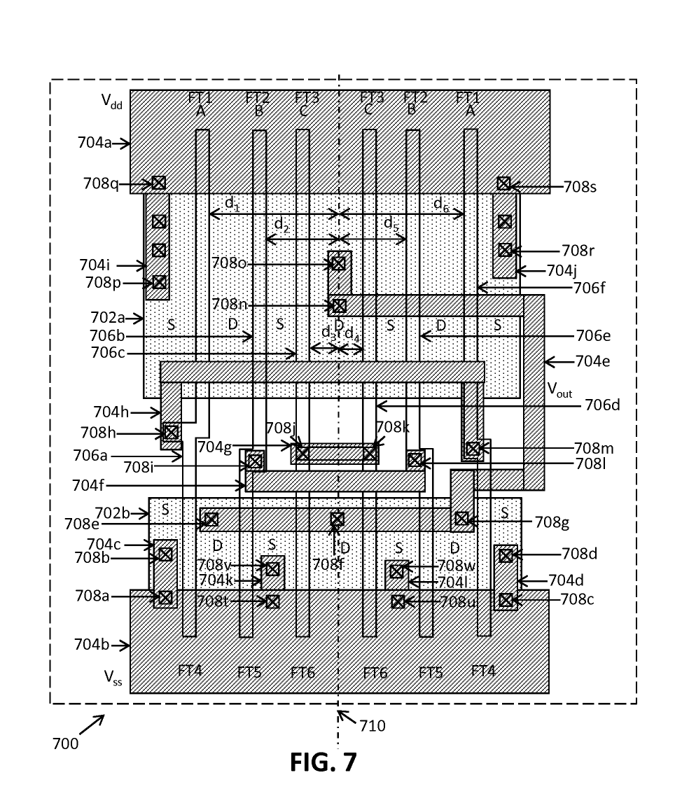

Referring now to FIG. 7, a schematic layout diagram of a standard cell 700 of a 3-input NOR gate in accordance with an embodiment of the present invention is shown. The standard cell 700 includes first and second active regions 702a and 702b, first through twelfth metal layers 704a-704l (collectively referred to as metal layers 704), first through sixth gate electrodes 706a-706f (collectively referred to as gate electrodes 706), and first through twenty-third metal contacts 708a-708w (collectively referred to as metal contacts 708). The metal layers 704 are implemented as power layers and signal layers. The signal layers route clock signals and input signals. The metal layers 704a and 704b form power supply (V_{dd}) and ground (vₛₛ) terminals, respectively. The gate electrodes 706 are disposed over the first and second active regions 702a and 702b. The first and sixth gate electrodes 706a and 706f form a first folded transistor FT1 in the first active region 702a and a fourth folded transistor FT4 in the second active region 702b. The second and fifth gate electrodes 706b and 706e form a second folded transistor FT2 in the first active region 702a and a fifth folded transistor FT5 in the second active region 702b. The third and fourth gate electrodes 706c and 706d form a third folded transistor FT3 in the first active region 702a and a sixth folded transistor FT6 in the second active region 702b. The first and second active regions 702a and 702b include a plurality of source and drain regions that are formed adjacent to the gate electrodes 706. The first, second, and third folded transistors FT1, FT2, and FT3 are PMOS transistors and the fourth, fifth, and sixth folded transistors FT4, FT5, and FT6 are NMOS transistors.

The first, second, and third gate electrodes 706a, 706b, and 706c are disposed on a first side of an axis 710 at first, second, and third distances d1, d2, and d3, respectively, from the axis 710. The fourth, fifth, and sixth gate electrodes 706d, 706e, and 706f are formed on a second side of the axis 710 at fourth, fifth, and sixth distances d4, d5, and d6, respectively, from the axis 710. The first and second distances d1 and d2 are greater than the third distance d3 and the fifth and sixth distances d5 and d6 are greater than the fourth distance d4. Further, the first distance d1 is greater than the second distance d2 and the sixth distance d6 is greater than the fifth distance d5. The gate electrodes 706 are disposed such that they are symmetric about the axis 710. The first gate electrode 706a is connected to the sixth gate electrode 706f by way of the metal layer 704h and the metal contacts 708h and 708m. The second gate electrode 706b is connected to the fifth gate electrode 706e by way of the metal layer 704f and the metal contacts 708i and 708l. The third gate electrode 706c is connected to the fourth gate electrode 706d by way of the metal layer 704g and the metal contacts 708j and 708k. The metal layers 704h, 704f, and 704g receive first, second, and third input signals, respectively. The metal layer 704a connects power supply (V_{dd}) to the source regions of the first folded transistor FT1 by way of the metal layer 704i and 704j and the metal contacts 708p, 708q, 708r, and 708s. The drain region of the third folded transistor FT3 that is formed between the third and fourth gate electrodes 706c and 706d is connected to the drain regions of the fourth, fifth, and sixth folded transistors FT4, FT5, and FT6 by the metal layer 704e by way of the metal contacts 708o, 708n, 708g, 708f, and 708e. The metal layer 704b connects ground to the source regions of the fourth folded transistor FT4 by way of the metal layers 704c, 704k, 704l, and 704d and the metal contacts 708a, 708b, 708t, 708v, 708u, 708w, 708c, and 708d. An output signal Vₒᵤₜ is obtained at the metal layer 704e.

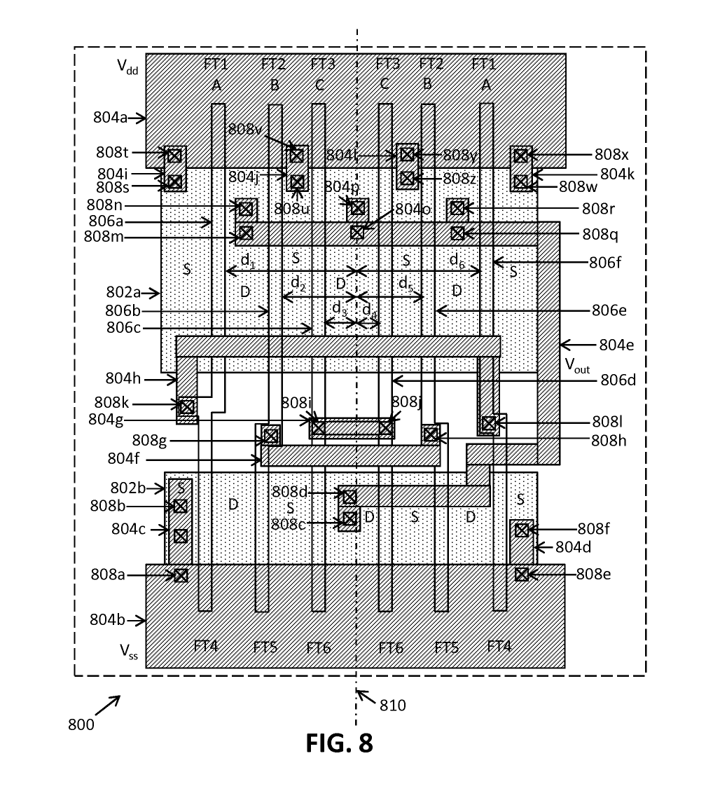

Referring now to FIG. 8, a schematic layout diagram of a standard cell 800 of a 3-input NAND gate in accordance with an embodiment of the present invention is shown. The standard cell 800 includes first and second active regions 802a and 802b, first through twelfth metal layers 804a-804l (collectively referred to as metal layers 804), first through sixth gate electrodes 806a-806f (collectively referred to as gate electrodes 806), and first through twenty-sixth metal contacts 808a-808z (collectively referred to as metal contacts 808). The metal layers 804 are implemented as power layers and signal layers. The signal layers route clock signals and input signals. The metal layers 804a and 804b form power supply (V_{dd}) and ground (vₛₛ) terminals, respectively. The gate electrodes 806 are disposed over the first and second active regions 802a and 802b. The first and sixth gate electrodes 806a and 806f form a first folded transistor FT1 in the first active region 802a and a fourth folded transistor FT4 in the second active region 802b. The second and fifth gate electrodes 806b and 806e form a second folded transistor FT2 in the first active region 802a and a fifth folded transistor FT5 in the second active region 802b. The third and fourth gate electrodes 806c and 806d form a third folded transistor FT3 in the first active region 802a and a sixth folded transistor FT6 in the second active region 802b. The first and second active regions 802a and 802b include a plurality of source and drain regions that are formed adjacent to the gate electrodes 806. The first, second, and third transistors FT1, FT2, and FT3 are PMOS transistors and the fourth, fifth, and sixth transistors FT4, FT5, and FT6 are NMOS transistors.

The first, second, and third gate electrodes 806a, 806b, and 806c are disposed on a first side of an axis 810 at first, second, and third distances d1, d2, and d3, respectively, from the axis 810. The fourth, fifth, and sixth gate electrodes 806d, 806e, and 806f are formed on a second side of the axis 810 at fourth, fifth, and sixth distances d4, d5, and d6, respectively, from the axis 810. The first and second distances d1 and d2 are greater than the third distance d3 and the fifth and sixth distances d5 and d6 are greater than the fourth distance d4. Further, the first distance d1 is greater than the second distance d2 and the sixth distance d6 is greater than the fifth distance d5. The gate electrodes 806 are disposed such that they are symmetric about the axis 810. The first gate electrode 806a is connected to the sixth gate electrode 806f by way of the metal layer 804h and the metal contacts 808k and 808l. The second gate electrode 806b is connected to the fifth gate electrode 806e by way of the metal layer 804f and the metal contacts 808g and 808h. The third gate electrode 806c is connected to the fourth gate electrode 806d by way of the metal layer 804g and the metal contacts 808i and 808j. The metal layers 804h, 804f, and 804g receive first, second, and third input signals, respectively. The metal layer 804a connects power supply (V_{dd}) to the source regions of the first, second, and third folded transistors FT1, FT2, and FT3 by way of the metal layer 804i, 804j, 804l, and 804k and the metal contacts 808s, 808t, 808u, 808v, 808z, 808y, 808w, and 808x. The drain regions of the first, second, and third folded transistor FT1, FT2, and FT3 are connected to the drain region of the sixth folded transistor FT6 that is formed between the gate electrodes 806c and 806d by the metal layer 804e by way of the metal contacts 808m, 808n, 808o, 808p, 808q, 808r, 808c, and 808d. The metal layer 804b connects ground to the source regions of the fourth folded transistor FT4 by way of the metal layers 804c and 804d and the metal contacts 808a, 808b, 808e, and 808f. An output signal Vₒᵤₜ is obtained at the metal layer 804e.

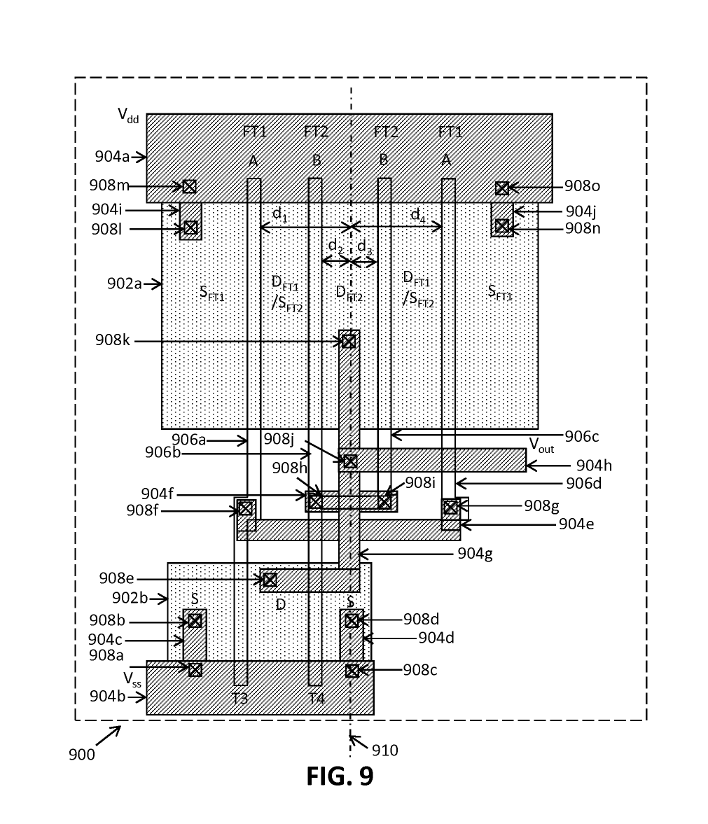

FIG. 9 is a schematic layout diagram of a standard cell layout 900 of a 2-input NOR gate in accordance with an alternate embodiment of the present invention. The standard cell 900 includes first and second active regions 902a and 902b, first through tenth metal layers 904a-904j (collectively referred to as metal layers 904), first through fourth gate electrodes 906a-906d (collectively referred to as gate electrodes 906), and first through fifteenth metal contacts 908a-908o (collectively referred to as metal contacts 908). The metal layers 904 implement power supply terminals and route clock signals and data signals. The metal layers 904a and 904b form power supply (V_{dd}) and ground (vₛₛ) terminals, respectively. The first and second gate electrodes 906a and 906b are disposed over the first and second active regions 902a and 902b while the third and fourth gate electrodes 906c and 906d are disposed only over the first active region 902a. The first and fourth gate electrodes 906a and 906d form a first folded transistor FT1 in the first active region 902a. The first gate electrode 906a forms a third transistor T3 in the second active region 902b. The second and third gate electrodes 906b and 906c form a second folded transistor FT2 in the first active region 902a. The second gate electrode 906b forms a fourth transistor T4 in the second active region 902b. The first and second active regions 902a and 902b include a plurality of source and drain regions that are formed adjacent to the gate electrodes 906. The first and second folded transistors FT1 and FT2 are PMOS transistors and the third and fourth transistors T3 and T4 are NMOS transistors.

The first and second gate electrodes 906a and 906b are disposed on a first side of an axis 910 at first and second distances d1 and d2, respectively, from the axis 910. The third and fourth gate electrodes 906c and 906d are formed on a second side of the axis 910 at third and fourth distances d3 and d4, respectively, from the axis 910. The first distance d1 is greater than the second distance d2 and the fourth distance d4 is greater than the third distance d3. The gate electrodes 906 are disposed such that they are symmetric about the axis 910 in the first active region 902a. The first gate electrode 906a is connected to the fourth gate electrode 906d by way of the metal layer 904e and the metal contacts 908f and 908g. The second gate electrode 906b is connected to the third gate electrode 906c by way of the metal layer 904f and the metal contacts 908h and 908i. The metal layers 904e and 904f receive first and second input signals, respectively. The metal layer 904a connects power supply (V_{dd}) to the source regions of the first folded transistor FT1 by way of the metal layers 904i and 904j and the metal contacts 908l, 908m, 908n, and 908o. The first and second folded transistors FT1 and FT2 share first and second portions of the first active region 902a that are formed on the first and second sides of the axis 910, respectively. The shared first portion on the first side of the axis 910 is formed between the gate electrodes 906a and 906b. The shared second portion on the second side of the axis 910 is formed between the gate electrodes 906c and 906d. The shared first and second portions of the first active region 902a form the drain and source regions of the first and second folded transistors FT1 and FT2, respectively. The drain region of the second folded transistor FT2 that is formed between the second and third gate electrodes 906b and 906c is connected to the drain region of the third and fourth transistors T3 and T4 by way of the metal layer 904g and the metal contacts 908e and 908k. The metal layer 904b connects ground to the source regions of the third and fourth transistors T3 and T4 by way of the metal layers 904c and 904d and the metal contacts 908a, 908b, 908c, and 908d. An output signal Vₒᵤₜ is obtained at the metal layer 904h by way of the metal contact 908j from the metal layer 904g.

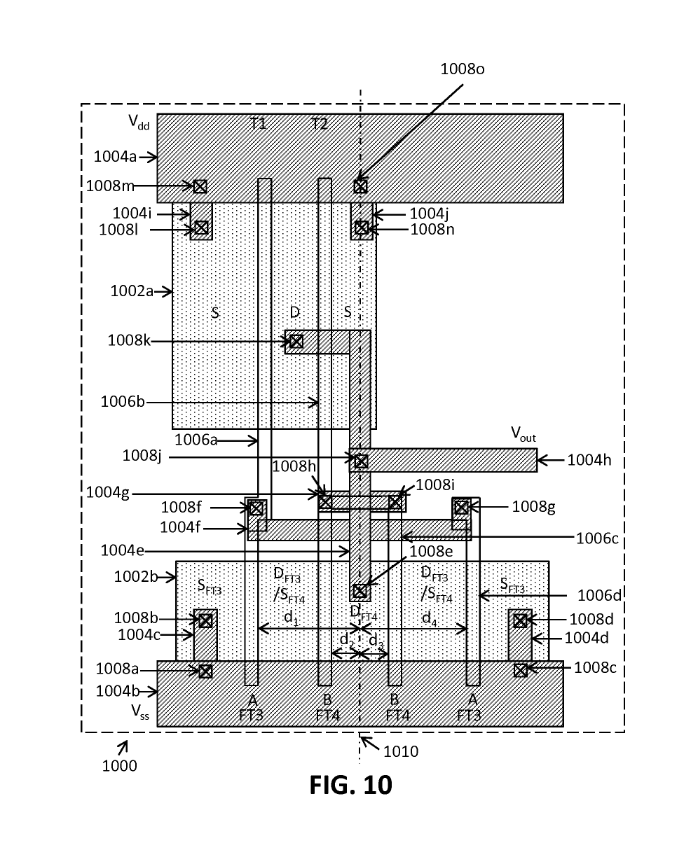

FIG. 10 is a schematic layout diagram of a standard cell layout 1000 of a 2-input NAND gate in accordance with an alternate embodiment of the present invention. The standard cell 1000 includes first and second active regions 1002a and 1002b, first through tenth metal layers 1004a-1004j (collectively referred to as metal layers 1004), first through fourth gate electrodes 1006a-1006d (collectively referred to as gate electrodes 1006), and first through fifteenth metal contacts 1008a-1008o (collectively referred to as metal contacts 1008). The metal layers 1004 implement power supply terminals and route clock signals, and data signals. The metal layers 1004a and 1004b form power supply (V_{dd}) and ground (vₛₛ) terminals, respectively. The gate electrodes 1006 are disposed over the first and second active regions 1002a and 1002b. The first gate electrode 1006a forms a first transistor T1 in the first active region 1002a. The first and fourth gate electrodes 1006a and 1006d form a third folded transistor FT3 in the second active region 1002b. The second gate electrode 1006b forms a second transistor T2 in the first active region 1002a. The second and third gate electrodes 1006b and 1006c form a fourth folded transistor FT4 in the second active region 1002b. The first and second active regions 1002a and 1002b include a plurality of source and drain regions that are formed adjacent to the gate electrodes 1006. The first and second transistors T1 and T2 are PMOS transistors and the third and fourth folded transistors FT3 and FT4 are NMOS transistors.

The first and second gate electrodes 1006a and 1006b are disposed on a first side of an axis 1010 at first and second distances d1 and d2, respectively, from the axis 1010. The third and fourth gate electrodes 1006c and 1006d are formed on a second side of the axis 1010 at third and fourth distances d3 and d4, respectively, from the axis 1010. The first distance d1 is greater than the second distance d2 and the fourth distance d4 is greater than the third distance d3. The gate electrodes 1006 are disposed such that they are symmetric about the axis 1010. The first gate electrode 1006a is connected to the fourth gate electrode 1006d by way of the metal layer 1004f and the metal contacts 1008f and 1008g. The second gate electrode 1006b is connected to the third gate electrode 1006c by way of the metal layer 1004g and the metal contacts 1008h and 1008i. The metal layers 1004f and 1004g receive first and second input signals, respectively. The metal layer 1004a connects power supply (V_{dd}) to the source regions of the first and second transistors T1 and T2 by way of the metal layers 1004i and 1004j and the metal contacts 1008l, 1008m, 1008n, and 1008o. The drain region of the first and second transistors T1 and T2 is connected to the drain region of the fourth folded transistor FT4 that is formed between the second and third gate electrodes 1006b and 1006c by the metal layer 1004e by way of the metal contacts 1008k and 1008e. The third and fourth folded transistors share first and second portions of the second active region 1002b that are formed on the first and second sides of the axis 1010, respectively. The shared first portion on the first side of the axis 1010 is formed between the gate electrodes 1006a and 1006b. The shared second portion on the second side of the axis 1010 is formed between the gate electrodes 1006c and 1006d. The shared first and second portions of the second active region 1002b form the drain region of the third folded transistor FT3 and the source region of the fourth folded transistor FT4. The metal layer 1004b connects ground to the source regions of the third folded transistor FT3 by way of the metal layers 1004c and 1004d and the metal contacts 1008a, 1008b, 1008c, and 1008d. An output signal Vₒᵤₜ is obtained at the metal layer 1004h by way of the metal contact 1008j from the metal layer 1004e.

While various embodiments of the present invention have been illustrated and described, it will be clear that the present invention is not limited to these embodiments only. Numerous modifications, changes, variations, substitutions, and equivalents will be apparent to those skilled in the art, without departing from the spirit and scope of the present invention, as described in the claims.

1. A standard cell layout, comprising:
a plurality of active regions including first and second active regions formed in a semiconductor substrate, wherein the first and second active regions are formed on first and second sides of a first axis, and the second active region is spaced from the first active region;
a plurality of gate fingers formed over the first and second active regions such that first and second gate fingers of the plurality of gate fingers are formed on the first side of the first axis, and third and fourth gate fingers of the plurality of gate fingers are formed on the second side of the first axis, wherein the first, second, third, and fourth gate fingers are substantially parallel to the first axis, and wherein the first, second, third, and fourth gate fingers are disposed at first, second, third, and fourth respective distances from the first axis, and wherein the first distance is greater than the second distance and the fourth distance is greater than the third distance; and
a plurality of gate connectors including first and second gate connectors that electrically connect the second and third gate fingers, and the first and fourth gate fingers,
respectively, such that the first active region forms a first folded transistor (FT2) with the first and fourth gate fingers and a second folded transistor (FT3) with the second and third gate fingers, and the second active region forms a third folded transistor (FT5) with the first and fourth gate fingers and a fourth folded transistor (FT6) with the second and third gate fingers.

2. The standard cell layout of claim 1, wherein the first, second, third, and fourth folded transistors (FT2, FT3, FT5, and FT6) each include at least one of a PMOS transistor and a NMOS transistor.

3. The standard cell layout of claim 1, wherein the first and second folded transistors (FT2 and FT3) are connected in series and the third and fourth folded transistors (FT5 and FT6) are connected in parallel, such that the standard cell forms a NOR gate.

4. The standard cell layout of claim 1, wherein the first and second folded transistors are connected in parallel, and the third and fourth folded transistors (FT5 and FT6) are connected in series, such that the standard cell forms a NAND gate.

5. The standard cell layout of claim 1, wherein the standard cell includes a tri-state logic circuit, an XOR gate, an XNOR gate, an AND gate, an OR gate, an AND-OR-Invert (AOI) gate, and an OR-AND-Invert (OAI) gate.

6. The standard cell layout of claim 1, wherein the first and second active regions have opposite conductivities.

7. The standard cell layout of claim 1, wherein the first and second active regions each includes at least one source region and at least one drain region.

8. The standard cell layout of claim 1, further comprising first and second power supply rail portions, wherein the first power supply rail portion is connected to a supply voltage and the second power supply rail portion is connected to ground.

9. The standard cell layout of claim 1, further comprising fifth and sixth gate fingers of the plurality of gate fingers, formed over the first and second active regions, wherein the fifth and sixth gate fingers are substantially parallel to the first axis, and wherein the fifth gate finger is formed on the first side of the first axis, and wherein the sixth gate finger is formed on the second side of the first axis, such that a fifth distance (d1) between the fifth finger and the first axis is greater than the second distance (d3) and a sixth distance (d6) between the sixth gate finger and the first axis is greater than the third distance (d4).

10. The standard cell layout of claim 9, further comprising a third gate connector that electrically connects the fifth and sixth gate fingers, respectively, such that the first active region forms a fifth folded transistor (FT1) with the fifth and sixth gate fingers, the second active region forms a sixth folded transistor (FT4) with the fifth and sixth gate fingers.

11. A standard cell layout, comprising:
a plurality of active regions including first and second active regions formed in a semiconductor substrate, wherein the first and second active regions (702a and 702b) are formed on first and second sides of a first axis, and the second active region is spaced apart from the first active region;
a plurality of gate fingers formed over the first and second active regions such that first, second, and third gate fingers of the plurality of gate fingers are formed on the first side of the first axis, and fourth, fifth and sixth gate fingers of the plurality of gate fingers are formed on the second side of the first axis, wherein the first, second, third, fourth, fifth, and sixth gate fingers are substantially parallel to the first axis, and the first, second, third, fourth, fifth, and sixth gate fingers are disposed at first, second, third, fourth, fifth, and sixth respective distances from the first axis, and wherein the first and second distances are greater than the third distance, and the fifth and sixth distances are greater than the fourth distance; and
a plurality of gate connectors including first, second, and third gate connectors that electrically connect the third and fourth gate fingers, the second and fifth gate fingers, and the first and sixth gate fingers, respectively, such that the first active region forms a first folded transistor (FT1) with the first and sixth gate fingers, a second folded transistor (FT2) with the second and fifth gate fingers, and a third folded transistor (FT3) with the third and fourth gate fingers, and the second active region forms a fourth folded transistor (FT4) with the first and sixth gate fingers, a fifth folded transistor (FT5) with the second and fifth gate fingers, and a sixth folded transistor (FT6) with the third and fourth gate fingers.

12. The standard cell layout of claim 11, wherein the first, second, third, fourth, fifth, and sixth folded transistors each includes at least one of a PMOS transistor and a NMOS transistor.

13. The standard cell layout of claim 11, wherein the first, second, and third folded transistors are connected in series and the fourth, fifth, and sixth folded transistors are connected in parallel, such that the standard cell forms a NOR gate.

14. The standard cell layout of claim 11, wherein the first, second, and third folded transistors are connected in parallel and the fourth, fifth, and sixth folded transistors are connected in series, such that the standard cell forms a NAND gate.

15. The standard cell layout of claim 11, wherein the first and second active regions have opposite conductivities.

16. The standard cell layout of claim 11, wherein the first and second active regions each includes at least one source region and at least one drain region.

17. The standard cell layout of claim 11, further comprising first and second power supply rail portions, wherein the first power supply rail portion is connected to a supply voltage and the second power supply rail portion is connected to ground.
